(19) United States
(12) Patent Application Publication
(10) Pub. No.: US 2025/0174579 A1
(43) Pub. Date: May 29, 2025

(54) SINGLE PIXEL MOISTURE PROTECTION (SPMP)

(71) Applicant: dpiX, LLC, Colorado Springs, CO (US)

(72) Inventors: Sara Chahid, Colorado Springs, CO (US); Jinhui Cho, Colorado Springs, CO (US); Jerome David Crocco, Colorado Springs, CO (US); Gregory Lee Hendy, Castle Rock, CO (US); Kevin Michael Thresher, Colorado Springs, CO (US)

(21) Appl. No.: 18/930,334

(22) Filed: Oct. 29, 2024

Related U.S. Application Data
(60) Provisional application No. 63/607,239, filed on Dec. 7, 2023.
(60) Provisional application No. 63/603,516, filed on Nov. 28, 2023.

(51) Int. Cl. H01L 23/00; H01L 27/146

(52) U.S. Cl. CPC H01L 23/564; H10F 39/011; H10F 39/189; H10F 39/804

(57) ABSTRACT

A moisture protected sensor array comprises a plurality of pixels, wherein each pixel is moisture protected by a single encapsulated organic layer segment that is isolated from single encapsulated organic layer segments of adjacent pixels.

### CROSS-REFERENCE TO RELATED APPLICATIONS

This application claims the benefit of U.S. Provisional Application No. 63/603,516, filed on Nov. 28, 2023 and U.S. Provisional Application No. 63/607,239, filed on Dec. 7, 2023, which applications are hereby incorporated herein by reference.

### TECHNICAL FIELD

The present invention relates generally to single pixel moisture protection (SPMP) for a sensor array and to a method for fabricating an SPMP sensor array.

### BACKGROUND

Traditional X-ray sensor panels typically utilize glass substrates that maintain stability against environmental conditions. However, emerging flexible substrates are susceptible to expansion and contraction due to temperature, humidity, and manufacturing conditions. Such changes impact the film stress of an inorganic passivation layer, potentially compromising its integrity and leading to moisture ingress.

### SUMMARY

According to an embodiment, a single pixel moisture protected sensor array comprises a plurality of sensors; a first inorganic layer over the plurality of sensors; an organic layer including a plurality of individually isolated organic layer segments over the inorganic layer and laterally extending over each of the plurality of sensors; and a second inorganic layer encapsulating each of the plurality of individually isolated organic layer segments.

According to an embodiment, a method for fabricating a single pixel moisture protected sensor array comprises forming a gate dielectric layer over a substrate, the gate dielectric layer including a gate for a thin film transistor (TFT); forming a drain, an island, a source, and a first metallization layer on a surface of the gate dielectric layer; forming a sensor of the first metallization layer; forming an inter-layer dielectric (ILD) over the TFT and the sensor; etching the ILD to provide vias to the drain and the sensor; forming a second metallization layer over the ILD; etching the second metallization layer to form contacts to the drain and the sensor; forming a first inorganic layer over the ILD and the contacts; forming an organic layer over the inorganic layer; etching the organic layer to form an organic layer segment laterally located over the sensor; and forming a second inorganic layer of the first inorganic layer and the organic layer.

According to an embodiment, a single pixel moisture protected sensor array comprising a plurality of pixels, wherein each pixel is moisture protected by a single encapsulated organic layer segment that is isolated adjacent single encapsulated organic layer segments of adjacent pixels.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1A is a plan view of a sensor array according to the prior art;

FIG. 1B is a plan view of a sensor array including single pixel moisture protection according to an embodiment;

FIG. 2 is a plan view of a sensor array including SPMP, wherein each pixel is isolated from an adjacent pixel by a row of dots therebetween, according to an embodiment;

FIG. 3 is a plan view of a sensor array including SPMP, wherein each pixel is isolated from an adjacent pixel by a slit therebetween, according to an embodiment;

FIG. 4 is a cross-sectional scanning electron microscope (SEM) view of a portion of two pixels of the sensor array including SPMP, according to an embodiment;

FIG. 5 is a cross-sectional view of a portion of two pixels of the sensor array according to a first SPMP embodiment;

FIG. 6 is a cross-sectional view of a portion of two pixels of the sensor array according to a second SPMP embodiment;

FIG. 7 is a cross-sectional view of a portion of two pixels of the sensor array according to a third SPMP embodiment; and

FIGS. 8-22 are cross-sectional views corresponding to processing steps of a method of fabricating an SPMP sensor array according to embodiments.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

In the following detailed description, reference is made to the accompanying drawings, which form a part hereof and in which are shown by way of illustrations specific embodiments in which the invention may be practiced. It is to be understood that other embodiments may be utilized and structural or logical changes may be made without departing from the scope of the present invention. For example, features illustrated or described for one embodiment can be used on or in conjunction with other embodiments to yield yet a further embodiment. It is intended that the present invention includes such modifications and variations. The examples are described using specific language, which should not be construed as limiting the scope of the appending claims. The drawings are not scaled and are for illustrative purposes only. For clarity, the same or similar elements have been designated by corresponding references in the different drawings if not stated otherwise.

To mitigate the expansion and contraction issue of traditional sensor arrays, an organic layer is introduced as a planarization layer under the inorganic passivation layer, according to embodiments. Some organic materials have very low water absorption. Most organic materials, however, have very high water absorption. If a sensor panel has particles or crack which penetrate passivation, this organic material can be shortcut for water travelling to or near a pixel. According to embodiments, each single pixel has its own organic layer which is not shared with an adjacent pixel.

According to embodiments, a flexible X-ray sensor panel is described below, advantageously designed to address the moisture-related challenges associated with non-rigid substrates.

Embodiments described below encompass a single pixel moisture protection (SPMP) sensor array, comprising a comprehensive system, methodology, and apparatus. The sensor array encapsulates all of the critical Thin-Film Transistor (TFT) elements and associated processes, encompassing metallic gate electrodes, gate dielectric films, semiconductor channels, as well as source and drain electrodes and other aspects described in further detail below.

The SPMP technology described below advantageously serves as a departure from the prevalent conventional flex approach, which is fraught with a multitude of challenges ranging from inadequate planarization, visible seams along sensor edges, to structural flaws like cracks, and scratches. These factors collectively bear a detrimental impact on the overall device performance, thereby considerably limiting its operational lifespan due to the emergence of defects and subsequent moisture ingress.

The SPMP technology can advantageously minimize the size of evolving pixels up to four pixels, which can lead to a reduction of heavy duty sealing to protect against moisture in the detector module.

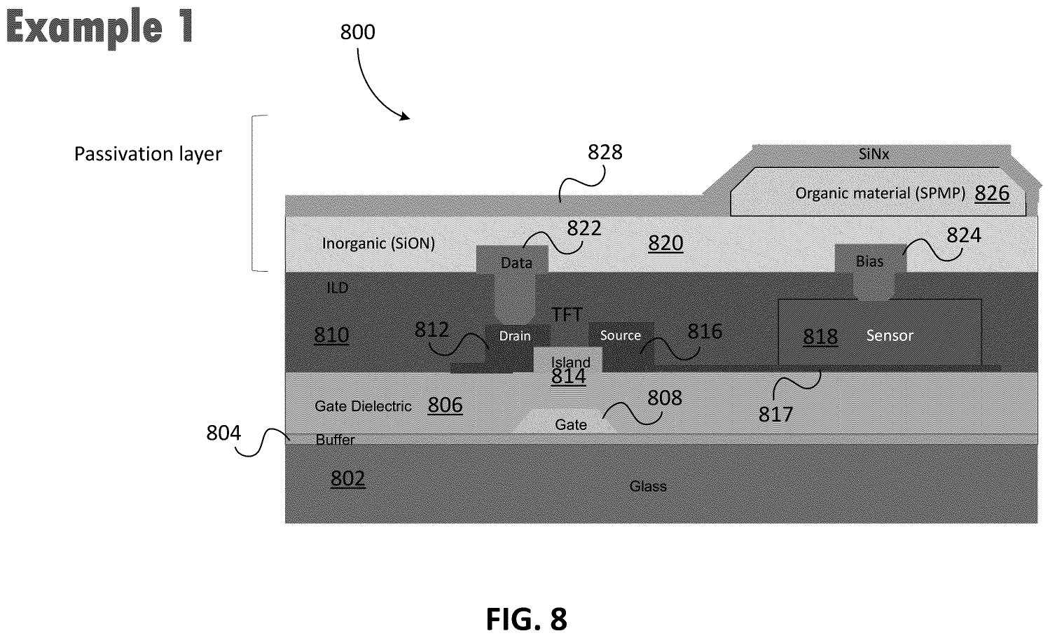

The SPMP technology requires several more process steps in the fabrication process when compared to some prior art solutions, which are described in further detail below particularly with respect to FIGS. 8-22.

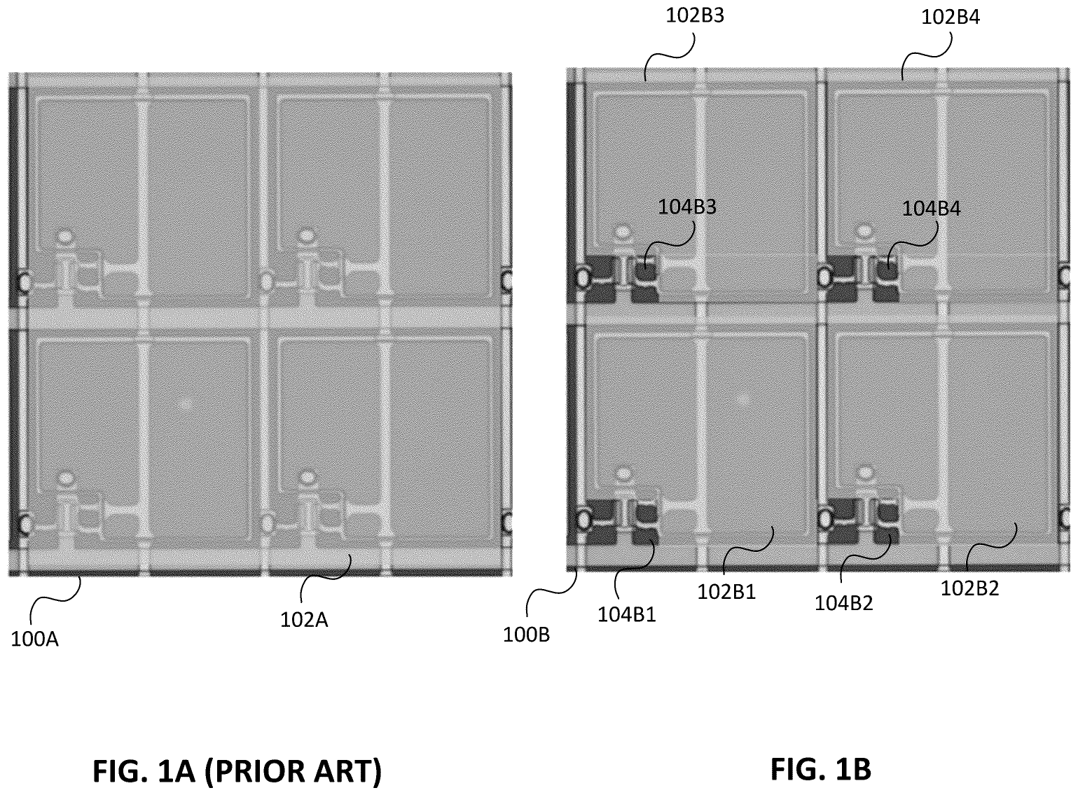

FIG. 1A is a plan view of a portion of a sensor array according to the prior art, wherein an organic layer 102A extends over the entire sensor array 100A, which can lead to moisture problems as described above.

FIG. 1B is a plan view of a portion of a sensor array 100B including single pixel moisture protection according to an embodiment. In FIG. 1B, four individual pixels are shown. An organic layer extends over the entire sensor array 100B, including a plurality of individually isolated organic layer segments 102B1, 102B2, 102B3, and 102B4. According to an embodiment, there is one individual isolated organic layer segment 102B1, 102B2, 102B3, and 102B4 per pixel. The individual isolated organic layer segments advantageously provide moisture protection, which is especially useful in flexible substrate embodiments. The organic layer is removed at the rest area, except for a sensor area. Removing the organic layer at the rest area provides additional benefits for laser repair. The rest area is the opening in the organic material layer, excluding the area to protect the pixel. Areas 104B1, 104B2, 104B3, and 104B4 are regions where the organic material film is removed. The benefit for laser repair is the ability to more easily access the TFT and fix defective pixels in order to improve yield. In prior art implementations (in which the TFT areas are covered with organic material), fixing defective pixels required an additional processing step to cut the TFT through the organic material. This solution sometimes led to an unstable manufacturing process.

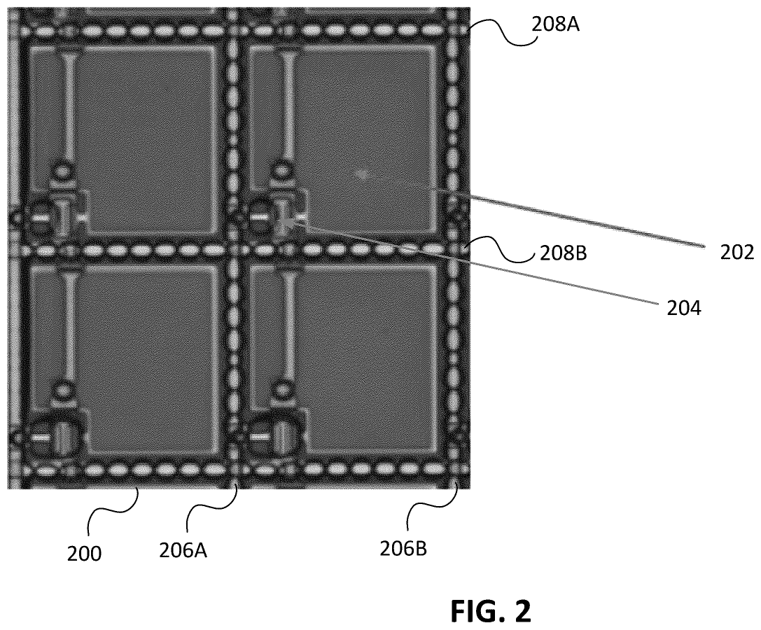

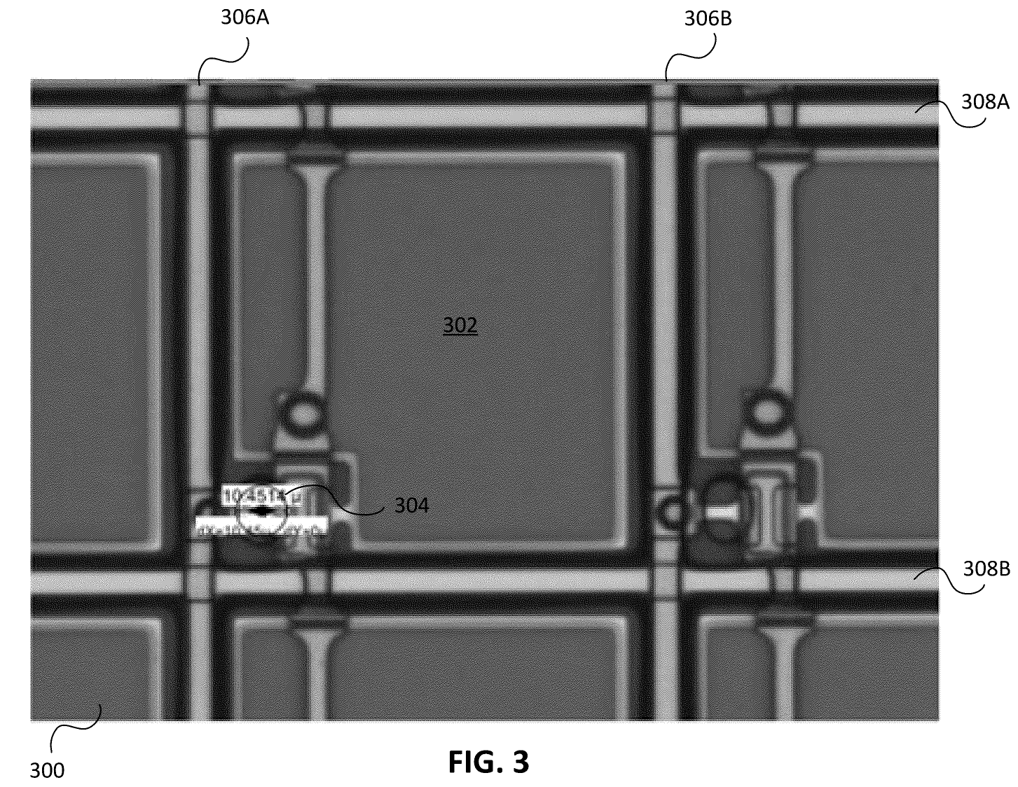

The SPMP approach according to embodiments ensures that defects and moisture molecules are effectively contained and restrained from migrating to adjacent pixels. The SPMP approach according to embodiments comprises several pixel isolation strategies, as is exemplified in FIG. 2 and FIG. 3, which are described in further detail below.

FIG. 2 is a plan view of a portion of a sensor array 200 including SPMP, wherein each pixel is isolated from an adjacent pixel by a row of dots (voids in the organic material layer) therebetween, according to an embodiment. More specifically, the layer of organic material covering the sensor array 200 is segmented and encapsulated into individual isolated organic layer segments. In FIG. 2 the portion of sensor array 200 includes four pixels. A representative pixel includes an individually isolated organic layer segment 202, with an exposed rest area 204. Rows of dots are used to define the organic material segments at the top and bottom of the pixel. A first row of dots 208A and a second row of dots 208B are shown in FIG. 2. Columns or rows of dots are used to define the organic material segments at the sides of the pixel. A first column of dots 206A and a second column of dots 206B are shown in FIG. 2. The horizontal and vertical dots in FIG. 2 are substantially the same in an embodiment. The dots are a hole in the organic material layer. In a color photomicrograph, color differences in the dots can appear from previous material layers and the lighting of an inspection tool. The area of both horizontal and vertical dots represents an area with no organic material. After etching, the dots open small, thin areas in the organic material layer. This isolates the organic layer in each of the pixels from each other. The organic layer isolation layer is shown in further detail and described below, especially with respect to the processing steps of a method of fabricating an SPMP sensor array shown in FIGS. 8 through 22.

The SPMP design, according to an embodiment, comprises dots with dimensions of about 3.5 μm×9 μm for the openings and a about a 2 μm gap between the dots. After etching, the 2 μm gap is removed, resulting in interconnected dots. This interconnected row of dots advantageously allows effective and manufacturable control the narrow gap between pixels.

A slit (gap or trench) design (shown in FIG. 3) serves as an alternative to the dot design in SPMP of FIG. 2, achieving pixel isolation by a different approach. FIG. 3 is a plan view of a sensor array 300 including SPMP, wherein each pixel is isolated from an adjacent pixel by a horizontal slit and a vertical slit therebetween. A single pixel of a sensor array 300 is shown in FIG. 3 including individual isolated organic layer segments. A representative pixel includes an isolated organic layer segment 302 and an exposed rest area 304. A first vertical slit 306A and a second vertical slit 306B are used to define the organic material segments at the sides of the pixel. A first horizontal slit 308A and a second horizontal slit 308B are used to define the organic material segments at the top and bottom of the pixel. The slits are etched trenches in the organic material layer, as will be shown and described in further detail below.

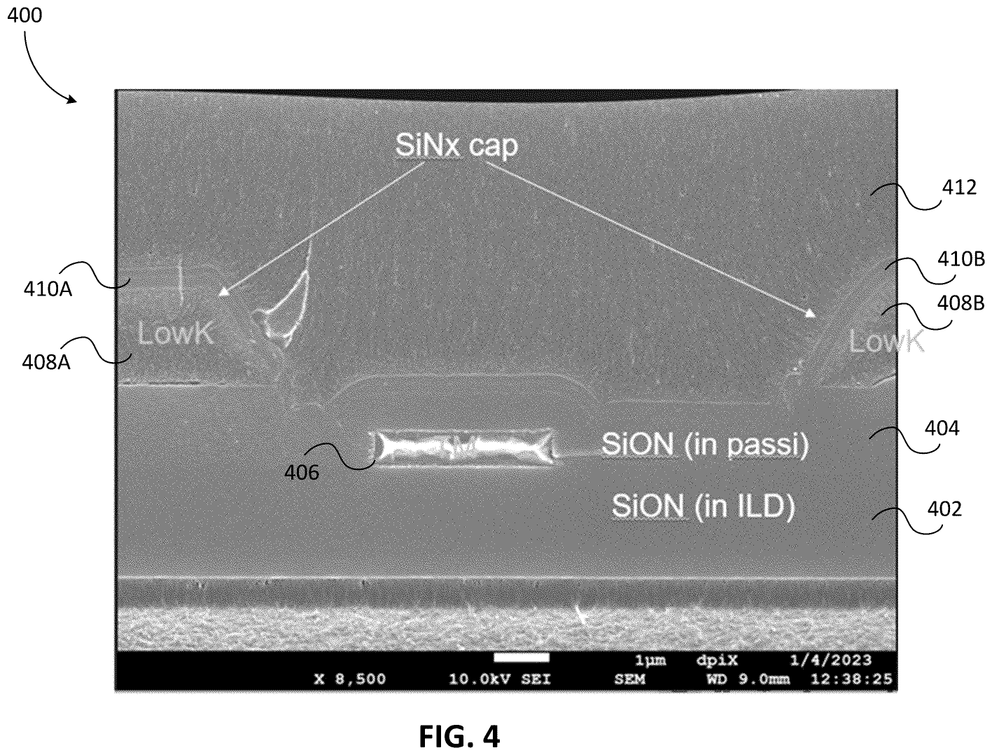

FIG. 4 is a cross-sectional scanning electron microscope (SEM) view of a portion of two pixels of a sensor array 400, according to an embodiment. Sensor array 400 includes a top metal data line (TM) 406 extending orthogonally to a plane of the SEM view, a SiON passivation layer 404, and a SiON inter-layer dielectric (ILD) layer 402. Sensor array 400 also includes an etched organic layer, including a first etched organic layer portion 408A associated with a first pixel, and a second etched organic layer portion 408B associated with a second pixel. The top metal layer is used for forming the data and bias lines of the pixel. The first etched organic layer portion 408A and the second etched organic layer portion 408B are also designed as a low relative dielectric constant layer (LowK) with respect to the silicon dioxide layers. Sensor array 400 also includes an etched SiNx cap layer (SiNx cap) over the etched organic layer, including a first etched SiNx cap layer portion 410A associated with the first pixel, and a second etched SiNx cap layer portion 410B associated with the second pixel. Finally, sensor array 400 includes a passivation layer, such as silicon dioxide or other suitable passivation materials. Additional layers and structures of the sensor array including, for example, layers and structures associated with a sensor and TFT are omitted in the SEM view shown in FIG. 4. These layers are shown in FIGS. 8-22 and discussed in further detail below.

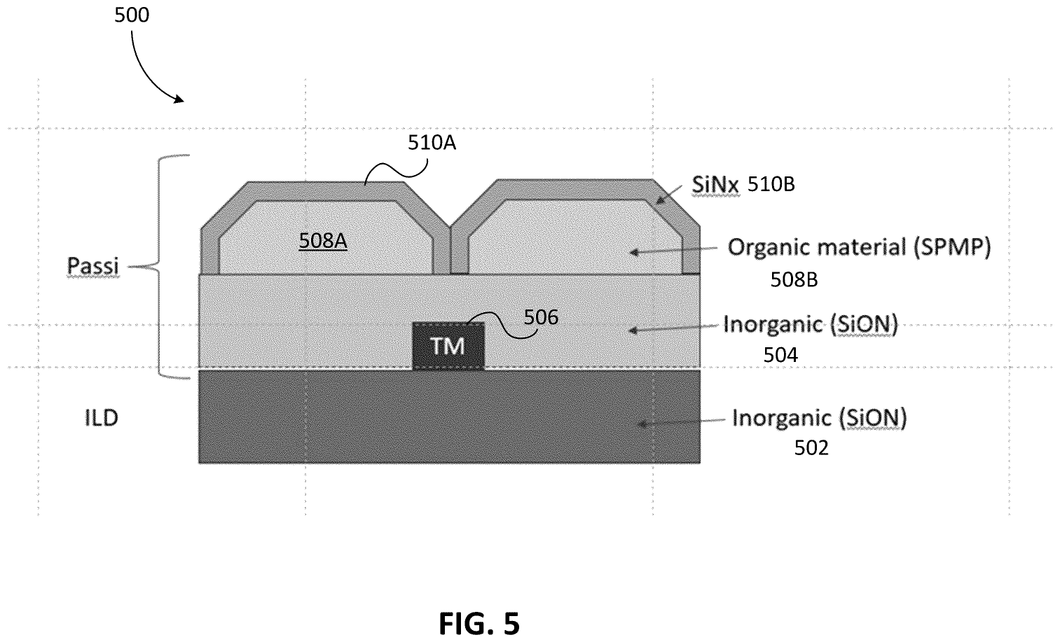

FIG. 5 is a cross-sectional view of a portion of two pixels of a sensor array 500 according to an embodiment similar to the cross-section SEM view of the sensor array 400 shown in FIG. 4. Sensor array 400 includes an inorganic SiON ILD layer 502, a data line 506 (TM), and passivation layers including an inorganic SiON layer 504 as well as an organic material layer and an SiNx capping layer. The organic material layer comprises a first organic material layer portion 508A associated with a first pixel and a second organic material layer portion 508B associated with a second pixel. The SiNx capping layer comprises a first SiNx capping layer portion 510A encapsulating the first organic material layer portion 508A and a second SiNx capping layer portion 510B encapsulating the second organic material layer portion 508B. In FIG. 5, a final passivation layer, sensor layers and structures, and TFT layers and structures are omitted for clarity.

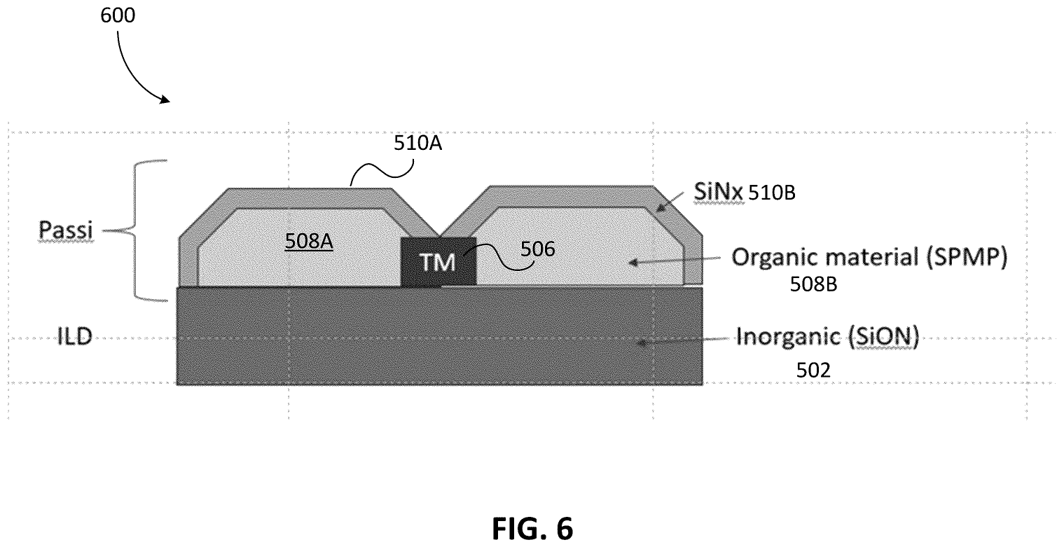

FIG. 6 is a cross-sectional view of a portion of two pixels of a sensor array 600 including an inorganic SiON ILD layer 502, a data line 506 (TM), and passivation layer, according to an embodiment. Sensor array 600 also includes an organic layer comprising a first organic material layer portion 508A associated with a first pixel and a second organic material layer portion 508B associated with a second pixel, and an SiNx capping layer comprising a first SiNx capping layer portion 510A encapsulating the first organic material layer portion 508A and a second SiNx capping layer portion 510B encapsulating the second organic material layer portion 508B. In pertinent part, sensor array 600 does not include the inorganic SiON layer 504 and moves the data line 506 to a boundary area between the first organic material layer portion 508A and the second organic material layer portion 508B. In FIG. 6, the final passivation layer, and the structures and layers associated with a sensor and TFT are omitted for clarity.

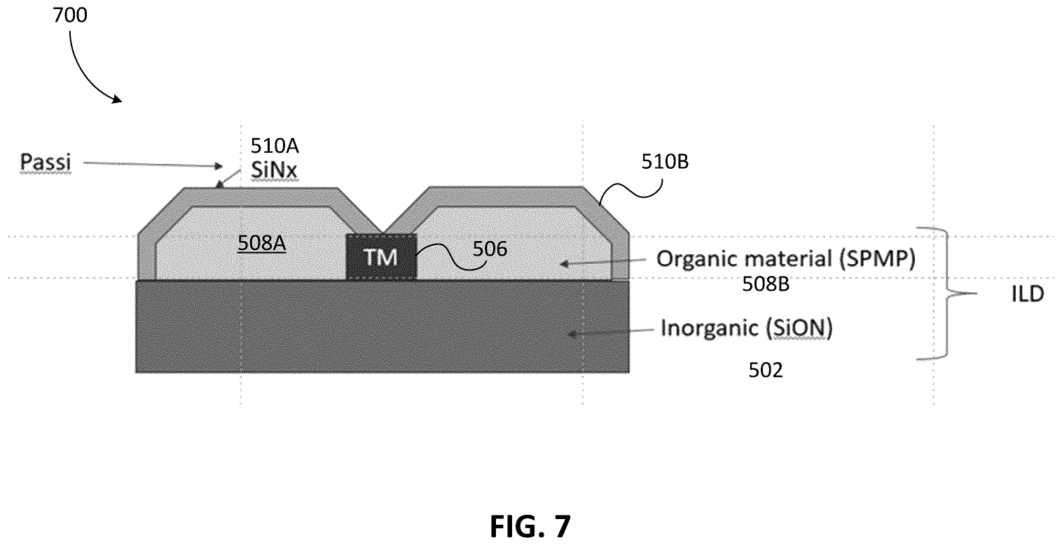

FIG. 7 is a cross-sectional view of a portion of two pixels of a sensor array 700, including the layers and structures previously described with respect to FIG. 6. Note, however, that the organic material layer and the inorganic SiON ILD layer 502 are considered part of the ILD structure of the sensor array 700. Thus, the embodiment of sensor array 600 shown in FIG. 6 and the embodiment of sensor array 700 shown in FIG. 7 appear similar in their final form, but the order of the processing steps are different. In FIG. 6, after a top metal etching step, the organic material layer (SPMP) and the SiNx layers are deposited as passivation layers. In FIG. 7, after the top metal etching step, only the SiNx layer is deposited as a passivation layer. The SPMP process in FIG. 7 is done prior to the data line 822 (TM) process as part of the interlayer dielectric (ILD).

FIGS. 8-22 are cross-sectional views of processing steps according to embodiments.

FIG. 8 is a cross-sectional view of a finished single pixel and a thin film transistor (TFT) image sensor device 800 including a glass or flexible substrate 802, a buffer layer 804, a gate dielectric layer 806 and a bottom positioned gate 808 that extends orthogonally to a plane of the cross-sectional view. Image sensor device 800 also includes an ILD layer 810 including the TFT transistor, and a passivation layer including the inorganic SiON layer 820 and the SiNx capping layer 828 for individually isolating the portion of organic material layer 826 according to the first SPMP embodiment. The TFT transistor includes a drain contact 812, an island 814, and a source contact 816. The drain contact 812 is coupled to a data line 822 extending orthogonally to a plane of the cross-sectional view. The sensor 818 includes a photo (PIN) diode with a transparent electrode such as Indium Tin Oxide (ITO), Indium Gallium Zinc Oxide (IGZO), and/or Aluminum doped Zinc Oxide (AZO) and is coupled to a bias line 824 extending orthogonally to a plane of the cross-sectional view. The TFT is coupled to sensor 818 via etched metallization layer 817.

In an embodiment, a flexible substrate 802 comprises polyimide (PI) on glass, buffer layer 804 comprises silicon nitride (SiNx) or a multi-layer of silicon nitride and silicon dioxide (SiNx/SiO₂), gate dielectric layer 806 comprises silicon nitride or silicon oxynitride (SiON), gate 808 comprises a composite layer of titanium tungsten, aluminum, and titanium tungsten (TiW/Al/TiW) or a composite layer of titanium tungsten, aluminum compound, and titanium tungsten (TiW/Al-compound/TiW) or a composite layer of molybdenum (Mo), aluminum and molybdenum (Mo/Al/Mo) or a composite layer of molybdenum (Mo), aluminum compound and molybdenum (Mo/Al-compound/Mo), ILD layer 810 comprises silicon oxynitride or a multi-layer of silicon oxynitride and silicon nitride, drain contact 812 and source contact 816 comprise phosphine doped amorphous Silicon (n+a-Si) or phosphine doped microcrystalline Silicon (n+uSi), island 814 comprises silicon nitride or silicon dioxide, etched metallization layer 817 comprises chromium (Cr) or a composite layer of chromium and titanium tungsten, data line 822 and bias line 824 comprise a composite layer of titanium tungsten, aluminum, and titanium tungsten, inorganic layer 820 comprises silicon oxynitride or a combination layer of silicon oxynitride and silicon nitride, capping layer 828 comprises silicon nitride or silicon dioxide, and organic material layer 826 comprises inorganic material like bisbenzocyclobutene (BCB).

In other embodiments the flexible substrate can comprise polymer materials such as polyimide (PI), poly(ethylene terephthalate) (PET), polyethylene naphthalate (PEN), and polycarbonate (PC). In other embodiments the sensor can comprise a doped or undoped amorphous silicon (a-Si) material, or a combination of these materials.

Additional details regarding the manufacturing of image sensor devices is found in U.S. Pat. No. 9,786,856 entitled “Method of Manufacturing an Image Sensor Device”; U.S. Pat. No. 9,853,084 entitled “Method of Manufacturing a Semiconductor Device”; U.S. Pat. No. 10,026,863 entitled “Method of Manufacturing a Sensor Array”; and U.S. Pat. No. 10,872,928 entitled “Method of Manufacturing an Enhanced High Performance Image Sensor Device”, all of which are hereby incorporated by reference.

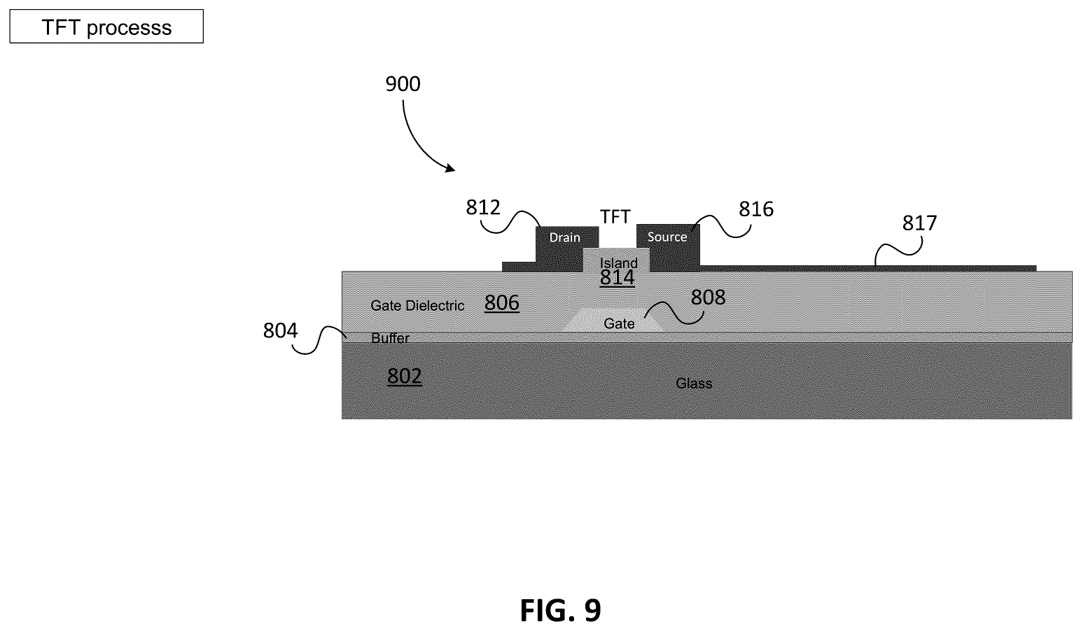

FIG. 9 is a cross-sectional view of the image sensor device 800 at a TFT processing step 900, according to the first SPMP embodiment, wherein the TFT is formed on a top surface of the gate dielectric layer 806, except for the bottom positioned gate 808. Thus, FIG. 9 shows the glass or flexible substrate 802, buffer layer 804, gate dielectric layer 806, gate 808, and drain contact 812, island 814, source contact 816, and etched metallization layer 817 formed on the top surface of the gate dielectric layer 806.

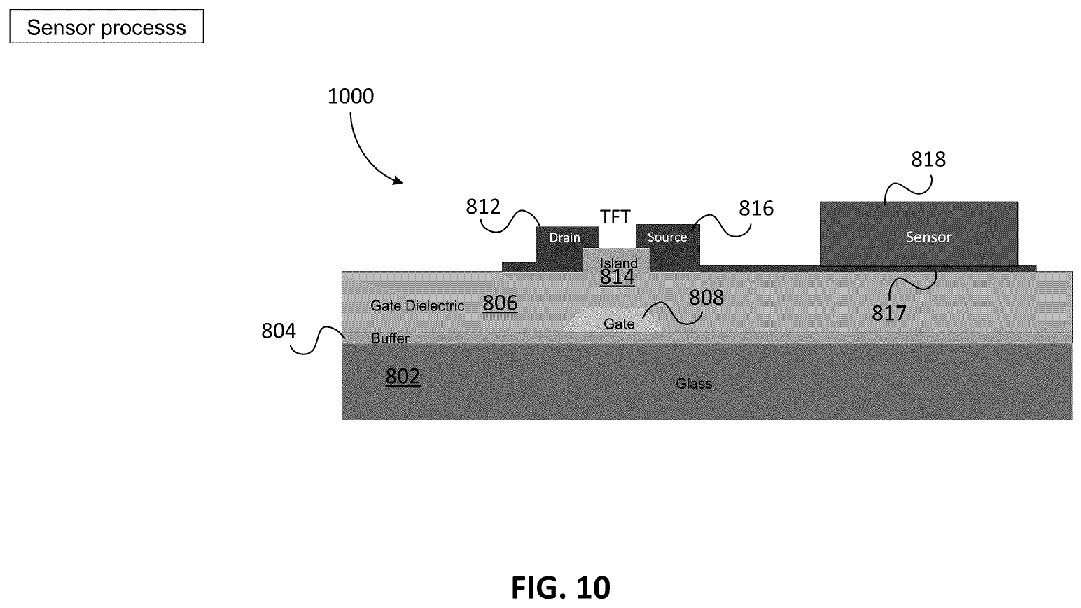

FIG. 10 is a cross-sectional view of the image sensor device 800 at a sensor processing step 1000, according to the first SPMP embodiment. A light sensitive sensor 818 is formed on the top surface of the gate dielectric layer 806. Etched metallization layer 817 is interposed between sensor 818 and gate dielectric layer 806.

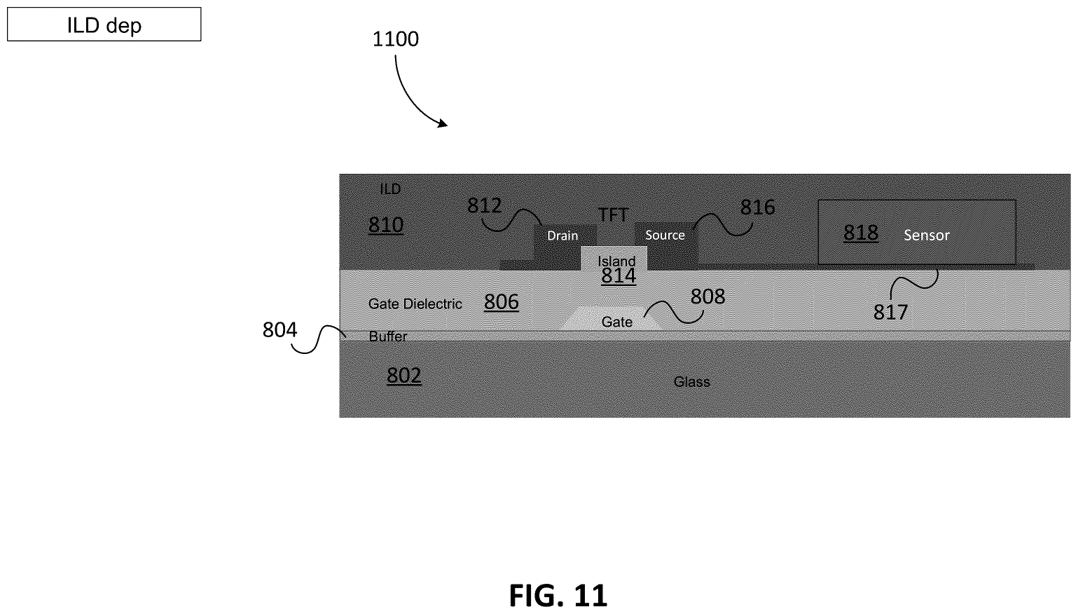

FIG. 11 is a cross-sectional view of the image sensor device 800 at an ILD deposition step 1100, according to the first SPMP embodiment. ILD layer 810 is formed over the TFT and sensor 818.

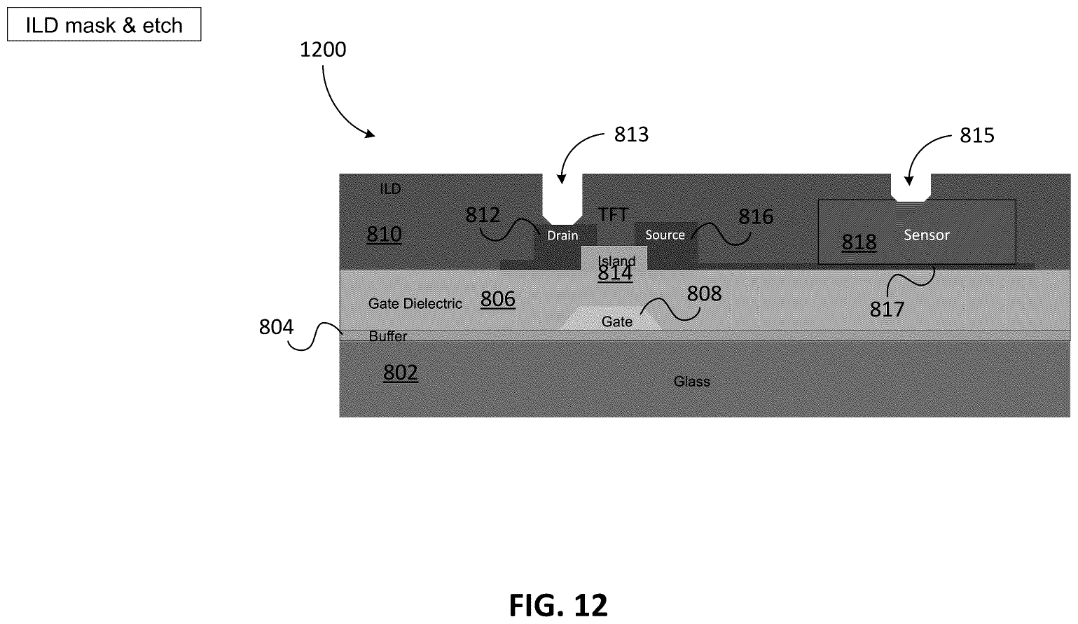

FIG. 12 is a cross-sectional view of the image sensor device 800 at an ILD masking and etch step 1200, according to the first SPMP embodiment. In FIG. 12, the ILD layer 810 is patterned and etched, wherein the ILD layer 810 is etched down to the drain contact 812 of the TFT through via 813 and etched down to the sensor 818 through via 815.

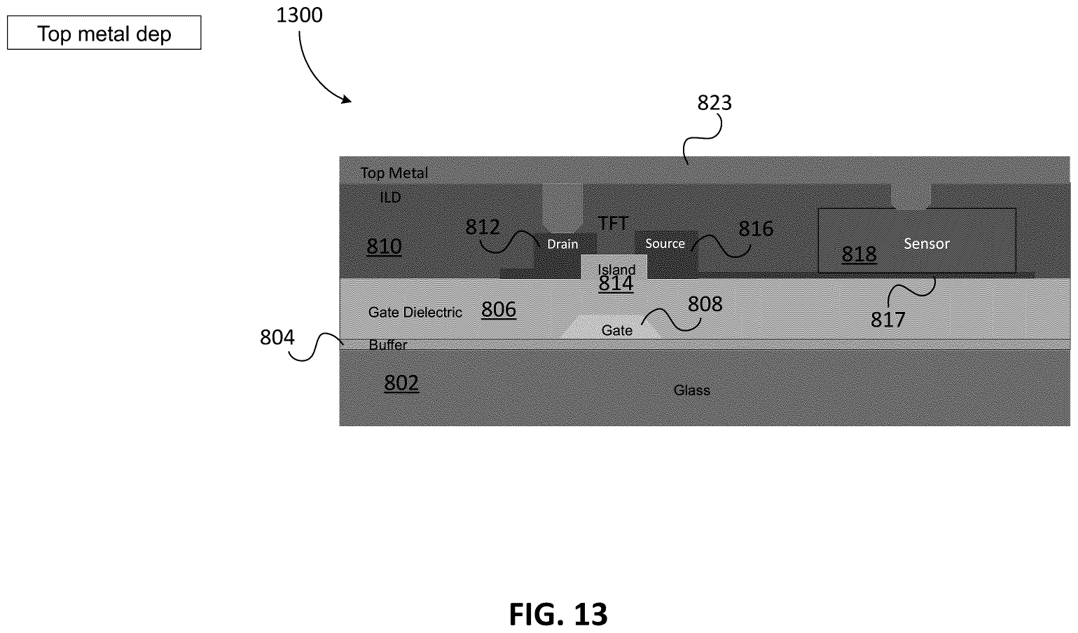

FIG. 13 is a cross-sectional view of the image sensor device 800 at a top metal layer deposition step 1300, according to the first SPMP embodiment. In FIG. 13, a top metal layer 823 is deposited on the surface of the ILD layer 810 such that the top metal layer 823 is coupled to the drain contact 812 and the sensor 818. Via 813 and via 815 are filled by the deposition of top metal layer 823 at top metal layer deposition step 1300.

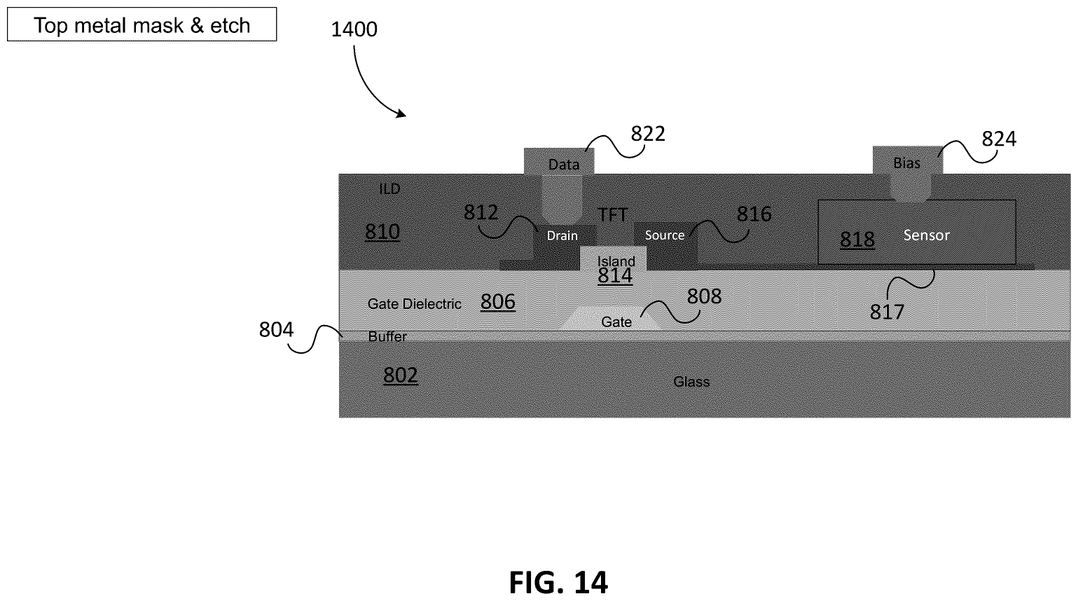

FIG. 14 is a cross-sectional view of the image sensor device 800 at a top metal masking and etching step 1400, according to the first SPMP embodiment. In FIG. 14, the top metal layer 823 is etched to form the data line 822 coupled to the drain contact 812 and the bias line 824 coupled to the sensor 818.

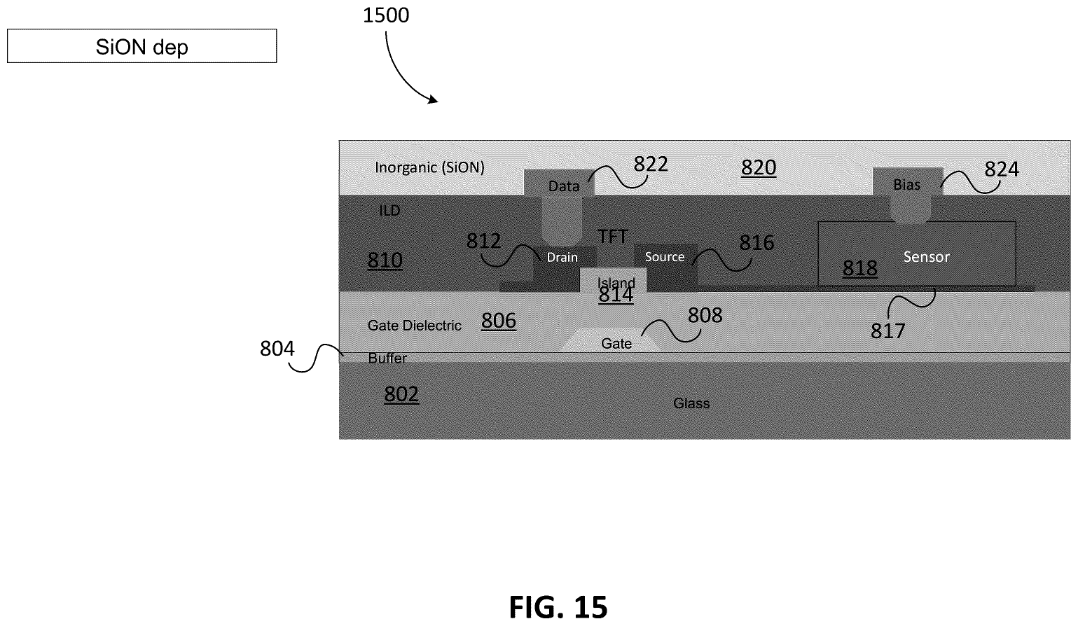

FIG. 15 is a cross-sectional view of the image sensor device 800 at a SiON layer deposition step 1500, according to the first SPMP embodiment. In FIG. 15, the SiON layer is deposited on a top surface of the ILD layer 810 and encapsulates the data line 822 and the bias line 824.

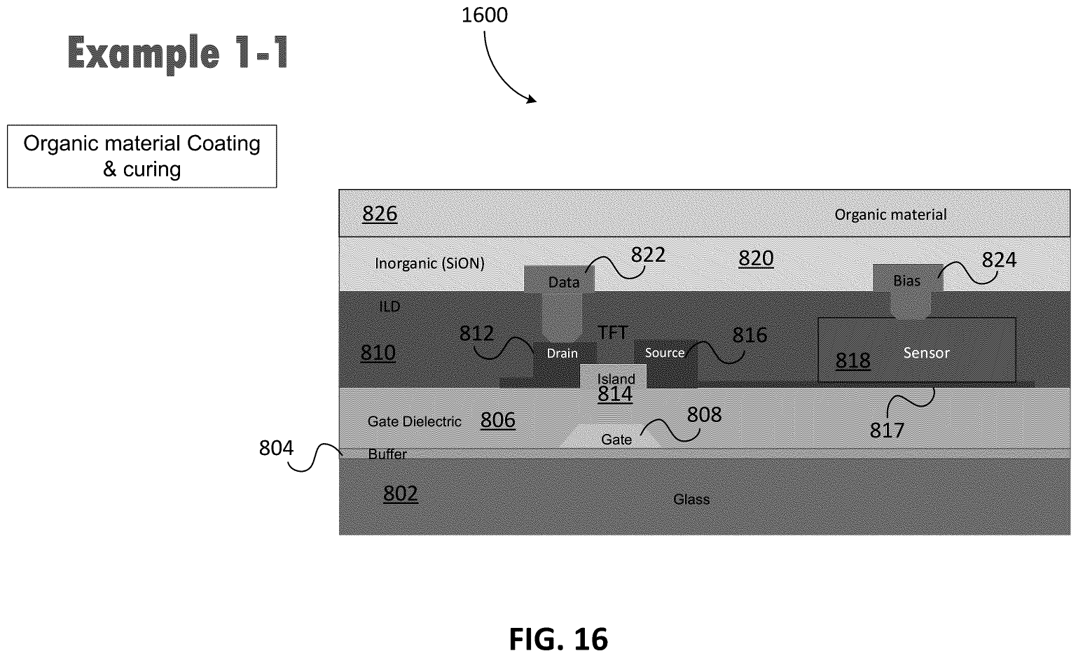

FIG. 16 is a cross-sectional view of the image sensor device 800 at the organic material layer coating and curing step 1600, according to the first SPMP embodiment, wherein the organic material layer 826 is formed on the top surface of the inorganic SiON layer 820.

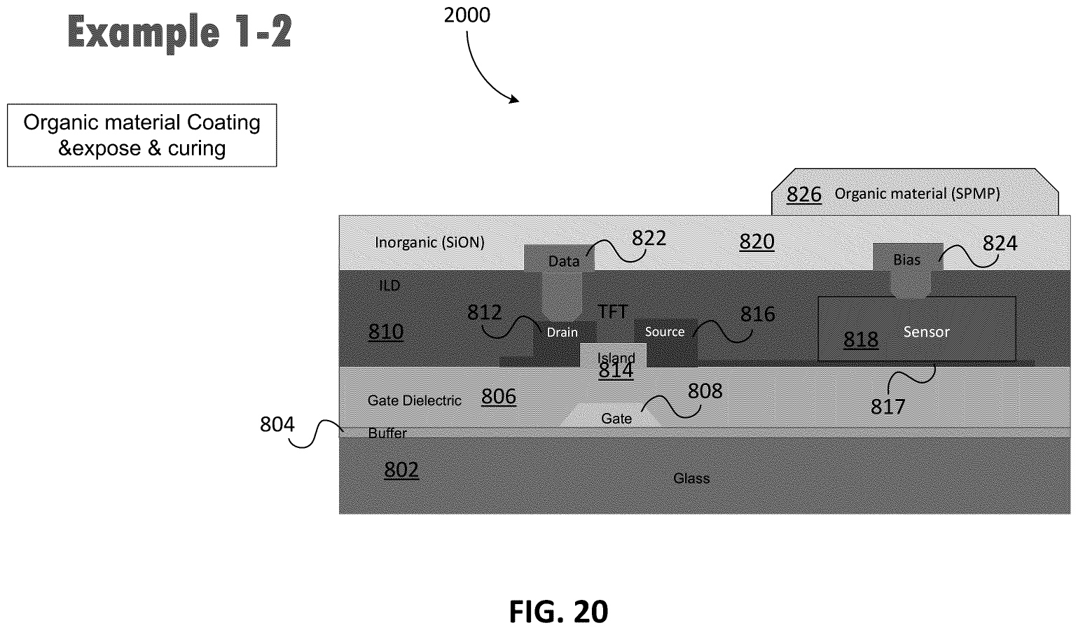

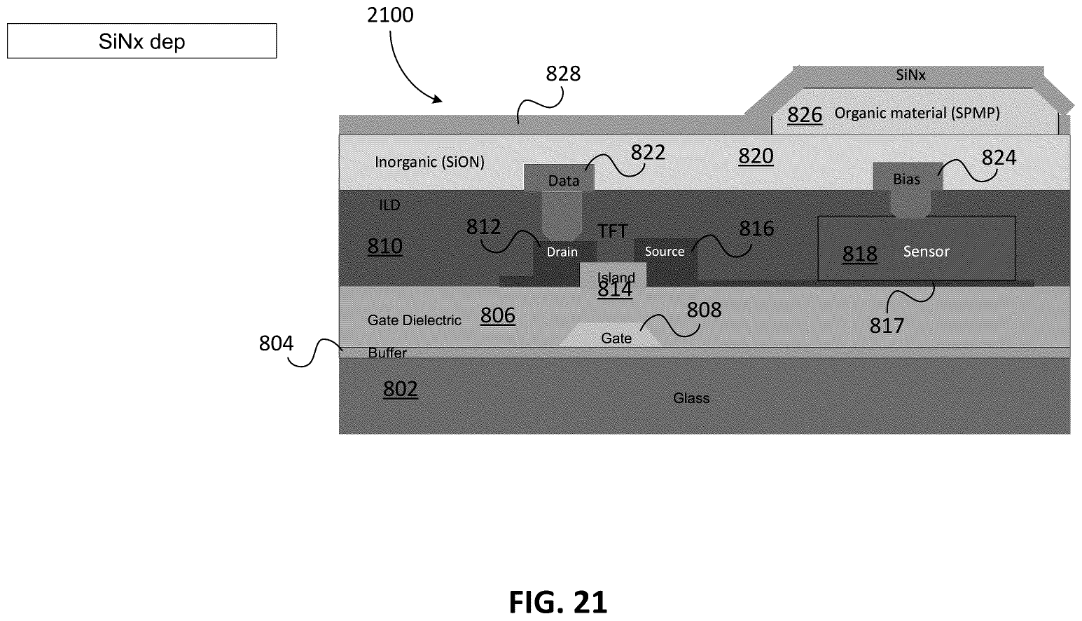

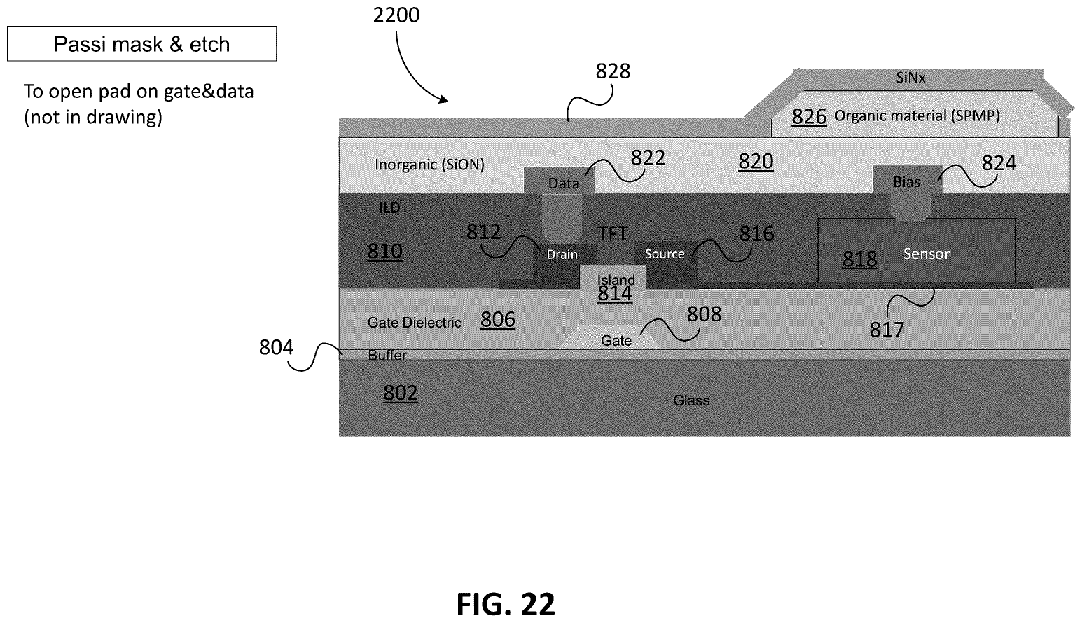

FIGS. 16-19 are designated Example 1-1, and FIG. 20 is designated Example 1-2. Examples 1-1 and 1-2 are associated with two processing embodiments. FIGS. 1-15 are associated with processing steps that are common to the two processing embodiments. After FIG. 15, in the first processing embodiment (Example 1-1) the processing steps of FIGS. 16, 17, 18, and 19 then FIGS. 21 and FIG. 22 are used. After FIG. 15, in the second processing embodiment (Example 1-2) the processing steps of only FIGS. 20, 21, and 22 are used.

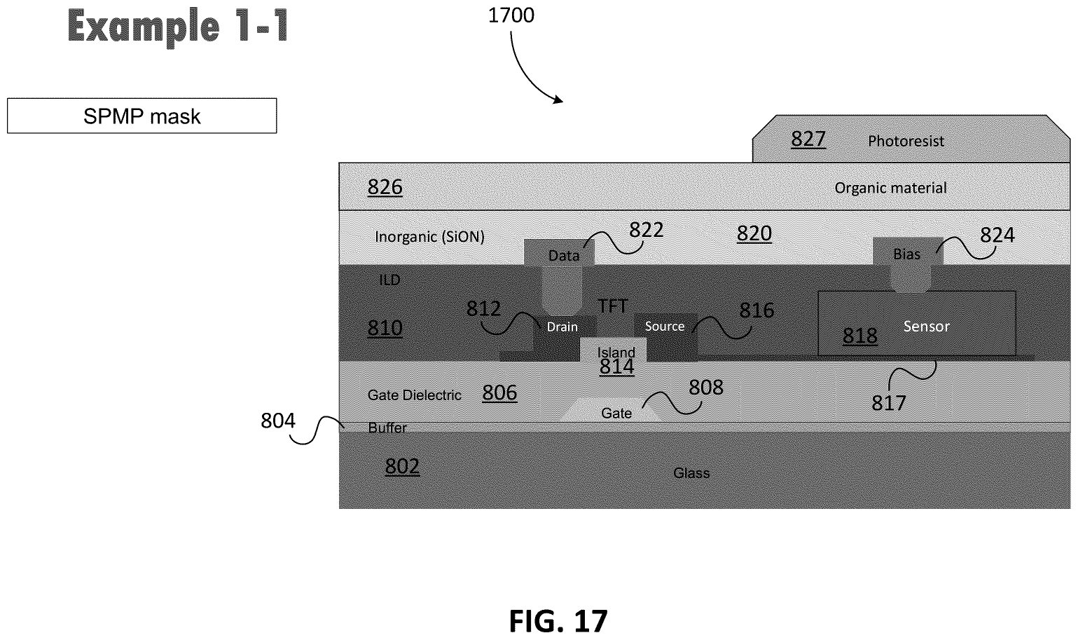

FIG. 17 is a cross-sectional view of a masking step 1700, according to the first SPMP embodiment, wherein a photoresist mask 827 is formed on the top surface of the organic material layer 826.

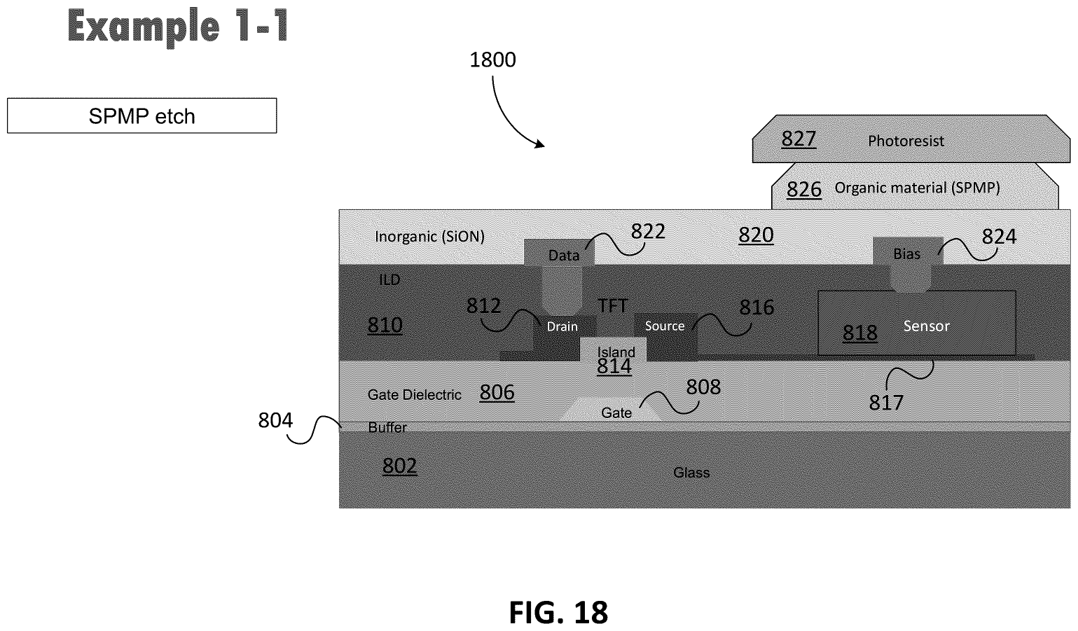

FIG. 18 is a cross-sectional view of an etching step 1800, according to the first SPMP embodiment, wherein the organic material layer 826 is etched to form a single pixel with its own isolated portion of the organic material layer 826 determined by the pattern of photoresist mask 827.

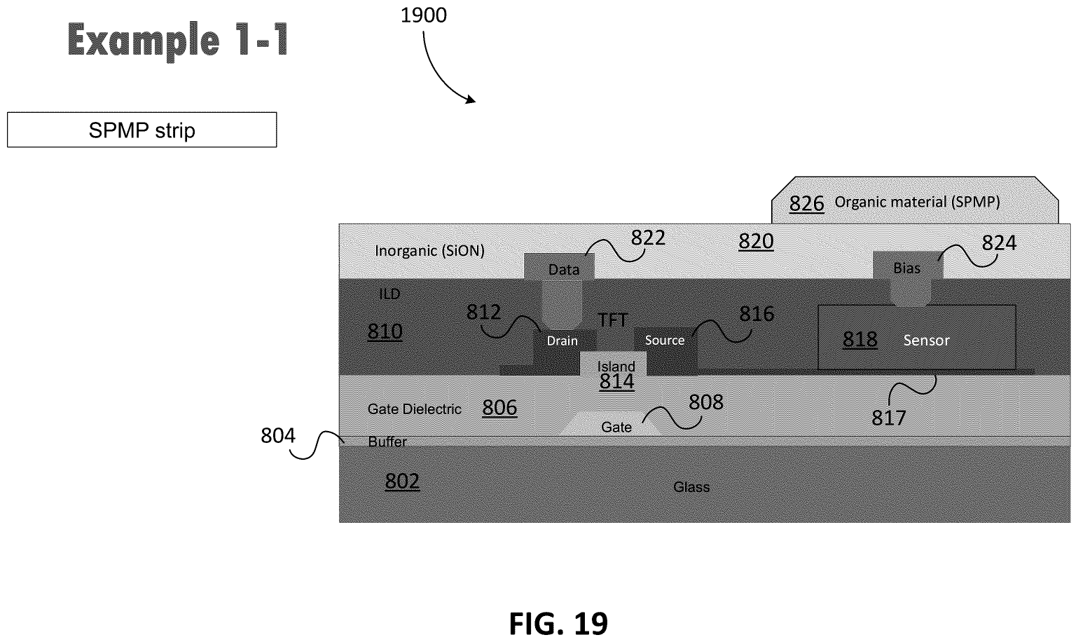

FIG. 19 is a cross-sectional view of a mask stripping step 1900, according to the first SPMP embodiment, wherein the photoresist mask 827 is stripped (that is, removed).

FIG. 20 is a cross-sectional view of an organic material coating, exposing, and curing step 2000 performed after SiON layer deposition step 1500 shown in FIG. 15, according to the second SPMP embodiment.

FIG. 21 is a cross-sectional view of SiNx layer deposition step 2100, according to the first and second SPMP embodiment, wherein the SiNx layer is deposited on a top surface of the inorganic SiON layer 820 and on a top surface of the etched organic material layer 826.

FIG. 22 is a cross-sectional view of a contact opening step 2200, according to the first and second SPMP embodiment, wherein pads are formed for the gate 808 and data lines 822 in a plane orthogonal to the drawing. The pads are thus not actually shown in the contact opening step of FIG. 22.

In summary, embodiments of a single pixel moisture protected sensor array have been shown and described comprising a plurality of sensors; a first inorganic layer over the plurality of sensors; an organic layer including a plurality of individually isolated organic layer segments over the inorganic layer and laterally extending over each of the plurality of sensors; and a second inorganic layer encapsulating each of the plurality of individually isolated organic layer segments.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A single pixel moisture protected sensor array comprising:
a plurality of sensors;
a first inorganic layer over the plurality of sensors;
an organic layer including a plurality of individually isolated organic layer segments over the inorganic layer and laterally extending over each of the plurality of sensors; and
a second inorganic layer encapsulating each of the plurality of individually isolated organic layer segments.

2. The single pixel moisture protected sensor array of claim 1, further comprising a glass or flexible substrate coupled to the first inorganic layer.

3. The single pixel moisture protected sensor array of claim 1, further comprising a data line in the first inorganic layer and laterally positioned underneath a boundary between adjacent organic layer segments.

4. The single pixel moisture protected sensor array of claim 1, further comprising a data line above the first inorganic layer at a boundary between adjacent organic layer segments.

5. The single pixel moisture protected sensor array of claim 1, wherein the first inorganic layer comprises silicon oxynitride (SiOₓN_{y}).

6. The single pixel moisture protected sensor array of claim 1, wherein the organic layer comprises an organic material having a low dielectric constant relative to that of silicon dioxide.

7. The single pixel moisture protected sensor array of claim 1, wherein the second inorganic layer comprises silicon nitride (SiNx).

8. The single pixel moisture protected sensor array of claim 1, further comprising a plurality of thin-film transistors (TFTs) in a one-to-one correspondence with the plurality of sensors.

9. The single pixel moisture protected sensor array of claim 8, wherein a portion of each of the individually isolated organic layer segments is removed to expose at last a portion of each of the plurality of TFTs.

10. A method for fabricating a single pixel moisture protected sensor array comprising:
forming a gate dielectric layer over a substrate, the gate dielectric layer including a gate for a thin film transistor (TFT);
forming a drain, an island, a source, and a first metallization layer on a surface of the gate dielectric layer;
forming a sensor of the first metallization layer;
forming an inter-layer dielectric (ILD) over the TFT and the sensor;
etching the ILD to provide vias to the drain and the sensor;
forming a second metallization layer over the ILD;
etching the second metallization layer to form contacts to the drain and the sensor;
forming a first inorganic layer over the ILD and the contacts;
forming an organic layer over the inorganic layer;
etching the organic layer to form an organic layer segment laterally located over the sensor; and
forming a second inorganic layer of the first inorganic layer and the organic layer.

11. The method of claim 10, wherein the substrate comprises a glass or flexible substrate.

12. The method of claim 11, wherein the flexible substrate comprises a polymer material.

13. The method of claim 10, wherein the sensor comprises an amorphous silicon material.

14. The method of claim 10, wherein the ILD comprises silicon oxynitride (SiOₓN_{y}).

15. The method of claim 10, wherein the first inorganic layer comprises silicon oxynitride (SiOₓN_{y}).

16. The method of claim 10, wherein the organic layer comprises an organic material having a low dielectric constant relative to that of silicon dioxide.

17. The method of claim 10, wherein the second inorganic layer comprises silicon nitride (SiNx).

18. The method of claim 10, further comprising a buffer layer interposed between the substrate and the gate dielectric layer.

19. A single pixel moisture protected sensor array comprising a plurality of pixels, wherein each pixel is moisture protected by a single encapsulated organic layer segment that is isolated from single encapsulated organic layer segments of adjacent pixels.

20. The single pixel moisture protected sensor array of claim 19, further comprising a flexible substrate configured for flexibly supporting the plurality of pixels.
